(19) United States
(12) Patent Application Publication
(10) Pub. No.: US 2012/0049188 A1
(43) Pub. Date: Mar. 1, 2012

(54) Method of forming polycrystalline silicon layer and thin film transistor and organic light emitting device including the polycrystalline silicon layer

(76) Inventors: Byoung-Keon Park, Yongin-City (KR); Tak-Young Lee, Yongin-city (KR); Jong-Ryuk Park, Yongin-city (KR); Yun-Mo Chung, Yongin-city (KR); Jin-Wook Seo, Yongin-city (KR); Ki-Yong Lee, Yongin-city (KR); Min-Jae Jeong, Yongin-city (KR); Yong-Duck Son, Yongin-city (KR); Byung-Soo So, Yongin-city (KR); Seung-Kyu Park, Yongin-city (KR); Kil-Won Lee, Yongin-city (KR); Dong-Hyun Lee, Yongin-city (KR); Jae-Wan Jung, Yongin-city (KR); Ivan Maidanchuk, Yongin-city (KR)

(21) Appl. No.: 13/137,276

(22) Filed: Aug. 3, 2011

(30) Foreign Application Priority Data
Aug. 26, 2010 (KR) 10-2010-0083049

(51) Int. Cl. H01L 29/04; H01L 29/786; H01L 21/20

(52) U.S. Cl. 257/52; 438/486; 257/66; 257/E21.09; 257/E29.273; 257/E29.003

(57) ABSTRACT

A method for forming a polycrystalline silicon layer includes: forming an amorphous silicon layer on a substrate; forming a metal catalyst on the amorphous silicon layer; forming a gettering metal layer on an overall surface of the amorphous silicon layer where the metal catalyst is formed; and performing a heat treatment. A thin film transistor includes the polycrystalline silicon layer, and an organic light emitting device includes the thin film transistor.

### BACKGROUND

1. Field

This disclosure relates to a method of forming a polycrystalline silicon layer, a thin film transistor including the polycrystalline silicon layer, and an organic light emitting device.

2. Description of the Related Art

A thin film transistor is a switching and/or driving device. A thin film transistor includes a gate line, a data line, and an active layer. The active layer mainly includes silicon, which may be classified as amorphous silicon or polycrystalline silicon, according to the state of crystallization.

Since polycrystalline silicon has high mobility compared with amorphous silicon, a thin film transistor including polycrystalline silicon may provide a rapid response speed and low power consumption.

Methods for forming polycrystalline silicon include solid-phase crystallization (SPC) and excimer laser crystallization (ELC). The solid-phase crystallization, however, may cause deformation of a substrate by performing a heat treatment at a high temperature for a long time. The excimer laser crystallization also has problems such as it requires expensive laser equipment and it is difficult to uniformly crystallize the overall substrate.

To complement the crystallization, there are such methods as a metal-induced crystallization (MIC) that performs crystallization using a metal catalyst, metal-induced lateral crystallization (MILC), and super-grain silicon crystallization (SGS). Such crystallization, however, may leave much metal catalyst on the polycrystalline silicon layer, which may affect the characteristics of the thin film transistor.

### SUMMARY

An exemplary embodiment of this disclosure provides a method for forming a polycrystalline silicon layer that may decrease the effect of a metal catalyst while improving a process.

Another embodiment of this disclosure provides a thin film transistor including a polycrystalline silicon layer formed through the method for forming a polycrystalline silicon layer.

Yet another embodiment of this disclosure provides an organic light emitting device including the thin film transistor.

According to an embodiment, there is provided a method for forming a polycrystalline silicon layer, including: forming an amorphous silicon layer on a substrate, forming a metal catalyst on the amorphous silicon layer, forming a gettering metal layer on an overall surface of the amorphous silicon layer where the metal catalyst is formed, and performing a heat treatment.

The heat treatment may be performed after the gettering metal layer is formed.

The performing of the heat treatment may include supplying oxygen gas to the gettering metal layer.

The heat treatment may be performed at a temperature ranging from about 500 to about 850° C.

The performing of the heat treatment may include performing a primary heat treatment after the forming of the amorphous silicon layer, and performing a secondary heat treatment after the forming of the gettering metal layer.

The performing of the secondary heat treatment may include supplying oxygen gas to the gettering metal layer.

The primary heat treatment may be performed at a temperature ranging from about 500 to about 850° C., and the secondary heat treatment may be performed at a temperature ranging from about 450 to about 750° C.

The metal catalyst may include one of nickel (Ni), silver (Ag), gold (Au), copper (Cu), aluminum (Al), tin (Sn), cadmium (Cd), palladium (Pd), an alloy thereof, and a combination thereof, and the gettering metal layer may include one of titanium (Ti), hafnium (Hf), scandium (Sc), zirconium (Zr), vanadium (V), tantalum (Ta), chromium (Cr), molybdenum (Mo), tungsten (W), manganese (Mn), rhenium (Re), ruthenium (Ru), osmium (Os), cobalt (Co), rhodium (Rh), iridium (Ir), platinum (Pt), yttrium (Y), lanthanum (La), cerium (Ce), praseodymium (Pr), neodymium (Nd), dysprosium (Dy), holmium (Ho), aluminum (Al), an alloy thereof, and a combination thereof.

The gettering metal layer may be formed in a thickness not thicker than about 1000 Å.

According to another embodiment, there is provided a thin film transistor, including a polycrystalline silicon layer formed according to a method described above, a gate insulation layer disposed on the polycrystalline silicon layer, a gate electrode disposed on the gate insulation layer and overlapping with the polycrystalline silicon layer; and a source electrode and a drain electrode electrically connected to the polycrystalline silicon layer.

The gate insulation layer may include a metal oxide.

The metal oxide may be formed by oxidation of the gettering metal layer during the performing of the heat treatment.

The gate insulation layer may have a thickness not thicker than about 1000 Å.

According to another embodiment, there is provided an organic light emitting device, including a polycrystalline silicon layer formed according to a method described above, a gate insulation layer disposed on the polycrystalline silicon layer, a gate electrode disposed on the gate insulation layer and overlapping with the polycrystalline silicon layer, a source electrode and a drain electrode electrically connected to the polycrystalline silicon layer, a pixel electrode electrically connected to the drain electrode, a common electrode confronting the pixel electrode, and an organic emission layer disposed between the pixel electrode and the common electrode.

The gate insulation layer may include a metal oxide.

The metal oxide may be formed by oxidation of the gettering metal layer during the performing of the heat treatment.

The gate insulation layer may have a thickness not thicker than about 1000 Å.

When polycrystalline silicon is formed through crystallization, a process may be simplified and the effect of remaining metal catalyst may be reduced. As a result, the characteristics of a thin film transistor may be improved.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A to 1E illustrate cross-sectional views sequentially depicting a method for forming a polycrystalline silicon layer in accordance with an embodiment of this disclosure.

FIGS. 2A to 2F illustrate cross-sectional views illustrating a method for forming a polycrystalline silicon layer in accordance with another embodiment of this disclosure.

FIG. 3 illustrates a cross-sectional view showing a thin film transistor in accordance with an embodiment of this disclosure.

FIG. 4 illustrates a cross-sectional view showing an organic light emitting device in accordance with an embodiment of this disclosure.

FIG. 5A illustrates a graph showing the concentration of nickel (Ni) distributed in a buffer layer, a polycrystalline silicon layer, and a gettering metal layer in a thin film transistor fabricated according to an example.

FIG. 5B illustrates a graph showing the concentration of nickel (Ni) distributed in a buffer layer and a polycrystalline silicon layer in a thin film transistor fabricated according to a comparative example.

### DETAILED DESCRIPTION

Korean Patent Application No. 10-2010-0083049, filed on Aug. 26, 2010, in the Korean Intellectual Property Office, and entitled: “Method of Forming Polycrystalline Silicon Layer and Thin Film Transistor and Organic Light Emitting Device Including the Polycrystalline Silicon Layer,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Like reference numerals refer to like elements throughout.

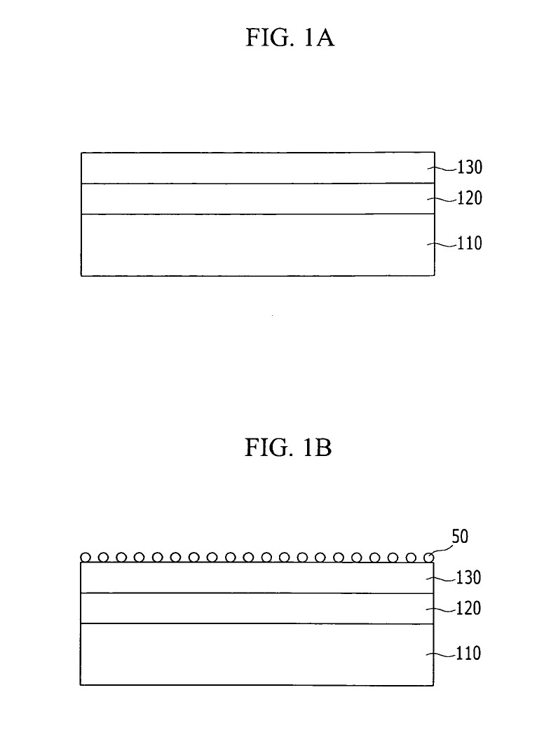

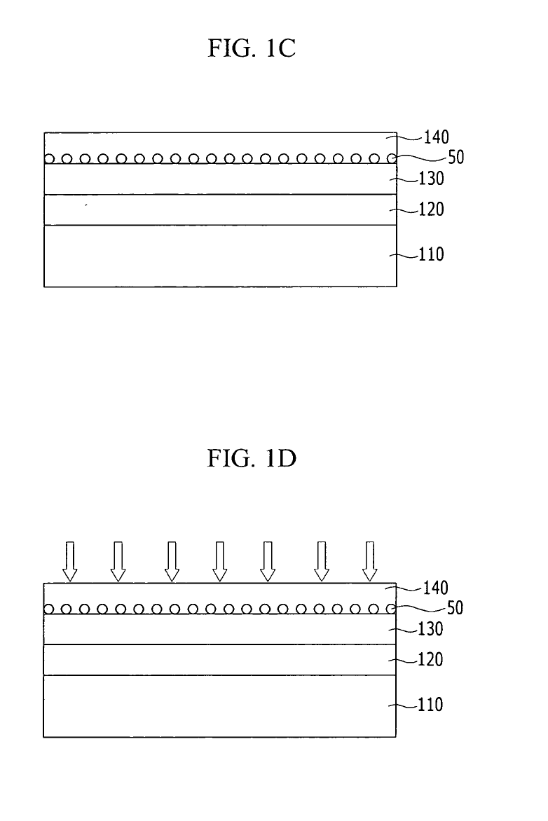

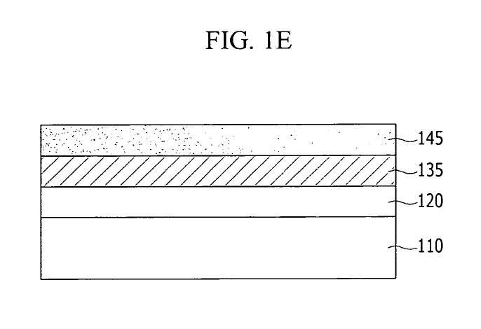

Hereafter, a method of forming a polycrystalline silicon layer in accordance with one embodiment will be described with reference to FIGS. 1A to 1E.

FIGS. 1A to 1E illustrate cross-sectional views sequentially depicting a method for forming a polycrystalline silicon layer in accordance with an embodiment of this disclosure.

Referring to FIG. 1A, a buffer layer 120 is formed on a substrate 110, which may be a glass substrate, a polymer substrate, or a silicon wafer substrate. The buffer layer 120 may be formed through a chemical vapor deposition (CVD) method using a chemical compound such as a silicon oxide or a silicon nitride. The buffer layer 120 cuts off the transfer of impurities from the substrate 110 or moisture introduced from the outside into the upper layers, and causes crystallization to be performed uniformly by controlling the heat transmission speed during a subsequent heat treatment.

Subsequently, an amorphous silicon layer 130 is formed on a buffer layer 120. The amorphous silicon layer 130 may be formed through a chemical vapor deposition (CVD) method using a gas, e.g., silane gas.

Referring to FIG. 1B, a metal catalyst 50 is formed on the amorphous silicon layer 130.

The metal catalyst 50 becomes seeds for crystallization by the heat treatment to be subsequently performed. The metal catalyst 50 may be formed in a low concentration according to super-grain silicon (SGS) crystallization. The metal catalyst 50 may be formed at a density ranging from about 1*10¹³ to about 1*10¹⁶ cm⁻². With a density within this range, the metal catalyst 50 may be catalyze the crystallization of a polycrystalline silicon layer having an appropriate crystallization size.

The metal catalyst 50 may be one of nickel (Ni), silver (Ag), gold (Au), copper (Cu), aluminum (Al), tin (Sn), cadmium (Cd), palladium (Pd), an alloy thereof, and a combination thereof.

Referring to FIG. 1C, a gettering metal layer 140 is formed over the amorphous silicon layer 130 where the metal catalyst 50 is formed.

The gettering metal layer 140 may fix or remove the metal catalyst 50 through the heat treatment to be subsequently performed. According to one embodiment, the gettering metal layer 140 may be formed through a sputtering method.

The gettering metal layer 140 may include a metal having a smaller diffusion coefficient than the above-described metal catalyst 50. According to one embodiment, the gettering metal layer 140 may include a metal haVing a diffusion coefficient of less than about 1/100 of the diffusion coefficient of the metal catalyst 50. Such a metal may include, for example, titanium (Ti), hafnium (Hf), scandium (Sc), zirconium (Zr), vanadium (V), tantalum (Ta), chromium (Cr), molybdenum (Mo), tungsten (W), manganese (Mn), rhenium (Re), ruthenium (Ru), osmium (Os), cobalt (Co), rhodium (Rh), iridium (Ir), platinum (Pt), yttrium (Y), lanthanum (La), cerium (Ce), praseodymium (Pr), neodymium (Nd), dysprosium (Dy), holmium (Ho), aluminum (Al), an alloy thereof, or a combination thereof.

The gettering metal layer 140 may be formed in a thickness less than about 1000 Å. According to one embodiment, the gettering metal layer 140 may have a thickness ranging from about 10 to about 1000 Å. When the thickness of the gettering metal layer 140 is within this range, a metal oxide layer that is uniform in the depth direction of the gettering metal layer 140 may be formed when a heat treatment is performed in an atmosphere of oxygen gas.

Referring to FIG. 1D, a heat treatment is performed on the substrate 110. During the heat treatment, some of the silicon that makes up the amorphous silicon layer 130 combines with the metal catalyst 50 to form a plurality of metal silicide particles, and a polycrystalline silicon layer 135 including a plurality of crystal particles is formed around the metal silicide. Also, during the heat treatment, the metal catalyst 50 diffuses upward into the gettering metal layer 140 to be collected at the inside or at the interface of the gettering metal layer 140.

Oxygen gas may be supplied to the gettering metal layer 140 during the heat treatment. When the heat treatment is performed while supplying oxygen gas to the gettering metal layer 140, the metal that constitutes the gettering metal layer 140 may be oxidized so as to form a metal oxide layer 145.

Accordingly, as illustrated in FIG. 1E, the buffer layer 120, the polycrystalline silicon layer 135, and the metal oxide layer 145 are sequentially stacked on the substrate 110. The metal oxide layer 145 may be removed or may be allowed to remain. When the metal oxide layer 145 is allowed to remain, the metal oxide layer 145 may be used as a gate insulation layer (which is a gate insulator) during the fabrication of a thin film transistor.

As described above, when the amorphous silicon layer is crystallized using the metal catalyst, the metal catalyst may be uniformly removed from the overall surface of the polycrystalline silicon layer by forming the gettering metal layer on the overall surface of the amorphous silicon layer and providing a heat treatment that causes the metal catalyst to uniformly diffuse from the amorphous silicon layer to the gettering metal layer. Accordingly, the metal catalyst scarcely remains on the polycrystalline silicon layer that is formed as the amorphous silicon layer is crystallized. A leakage current caused by the metal catalyst remaining in the thin film transistor including the polycrystalline silicon layer may be minimized and the characteristics of the thin film transistor may be improved.

During the heat treatment, the silicon-metal bond of the metal silicide positioned in the inside of the polycrystalline silicon layer 135 and on the interface between the polycrystalline silicon layer 135 and the metal oxide layer 145 is broken. A metal-oxygen bond may be formed by supplying oxygen gas during the heat treatment. Accordingly, little metal silicide remains inside of the polycrystalline silicon layer 135 and on the interface between the polycrystalline silicon layer 135 and the metal oxide layer 145, and the leakage current caused by the metal silicide may be reduced.

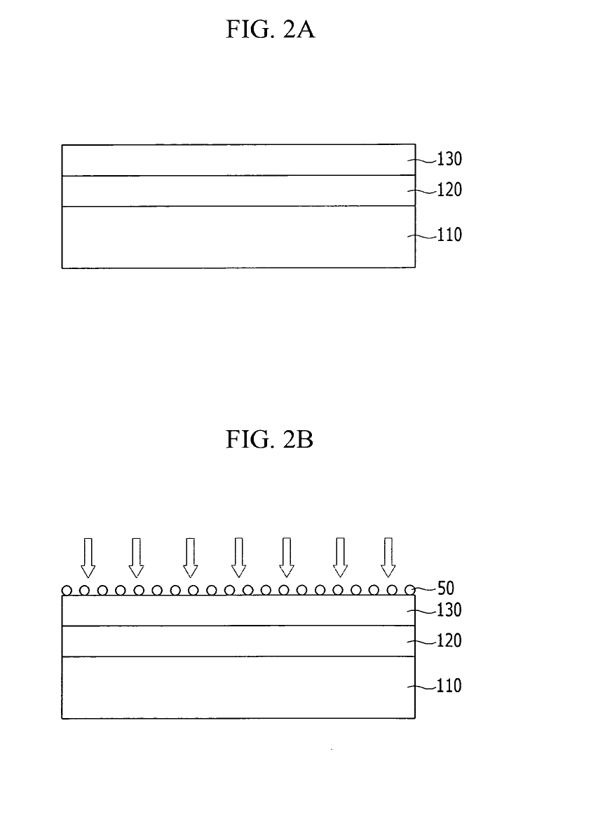

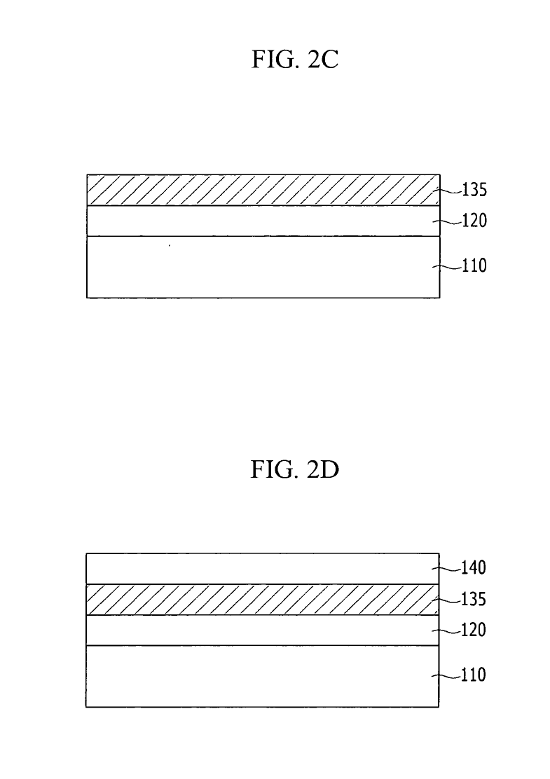

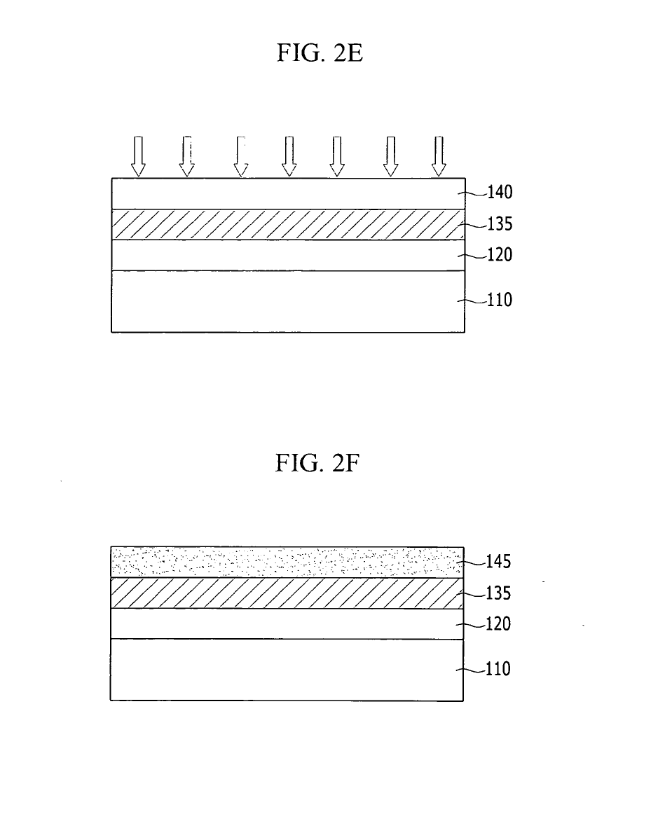

Hereafter, a method for forming a polycrystalline silicon layer in accordance with another embodiment of this disclosure will be described with reference to FIGS. 2A to 2E.

FIGS. 2A to 2E illustrate cross-sectional views depicting a method for forming a polycrystalline silicon layer in accordance with another embodiment of this disclosure.

Referring to FIG. 2A, a buffer layer 120 and an amorphous silicon layer 130 are sequentially formed on a substrate 110, e.g., a glass substrate, a polymer substrate, or a silicon wafer. The buffer layer 120 and the amorphous silicon layer 130 may be formed sequentially through a method such as a chemical vapor deposition (CVD) method.

Referring to FIG. 2B, a metal catalyst 50 is formed on the amorphous silicon layer 130. The metal catalyst 50 may be one of nickel (Ni), silver (Ag), gold (Au), copper (Cu), aluminum (Al), tin (Sn), cadmium (Cd), an alloy thereof, and a combination thereof. The metal catalyst 50 may be formed in a density of 1*10¹³ to about 1*16 _{cm}⁻².

Subsequently, a primary heat treatment is provided to the amorphous silicon layer 130 with the metal catalyst 50.

The amorphous silicon layer 130 is crystallized through the heat treatment using the metal catalyst 50 as crystal seeds. Accordingly, as shown in FIG. 2C, the substrate 110, the buffer layer 120, and the polycrystalline silicon layer 135 may be sequentially stacked. At this time, the metal catalyst 50 remains in the polycrystalline silicon layer 135.

Referring to FIG. 2D, a gettering metal layer 140 is formed on the overall surface of the polycrystalline silicon layer 135. The gettering metal layer 140 may be formed in a thickness of about 1000 Å, and may include, for example, a metal that is titanium (Ti), hafnium (Hf), scandium (Sc), zirconium (Zr), vanadium (V), tantalum (Ta), chromium (Cr), molybdenum (Mo), tungsten (W), manganese (Mn), rhenium (Re), ruthenium (Ru), osmium (Os), cobalt (Co), rhodium (Rh), iridium (Ir), platinum (Pt), yttrium (Y), lanthanum (La), cerium (Ce), praseodymium (Pr), neodymium (Nd), dysprosium (Dy), holmium (Ho), aluminum (Al), an alloy thereof, or a combination thereof.

Referring to FIG. 2E, a secondary heat treatment is performed on the gettering metal layer 140. The heat treatment may diffuse and fix the metal catalyst 50 remaining in the polycrystalline silicon layer 135 into and onto the gettering metal layer 140. Accordingly, the metal catalyst 50 is removed from the polycrystalline silicon layer 135. A leakage current caused by the metal catalyst remaining in a thin film transistor including the polycrystalline silicon layer may be minimized and the characteristics of the thin film transistor may be increased.

Oxygen gas may be supplied to the gettering metal layer 140 during the secondary heat treatment. As described above, when the heat treatment is performed while supplying oxygen gas to the gettering metal layer 140, the metal constituting the gettering metal layer 140 is oxidized to form a metal oxide layer 145.

As a result, as illustrated in FIG. 2F, the buffer layer 120, the polycrystalline silicon layer 135, and the metal oxide layer 145 may be sequentially stacked on the substrate 110. The metal oxide layer 145 may be removed or may be allowed to remain. When the metal oxide layer 145 is allowed to remain, the metal oxide layer 145 may be used as a gate insulation layer during the formation of a thin film transistor.

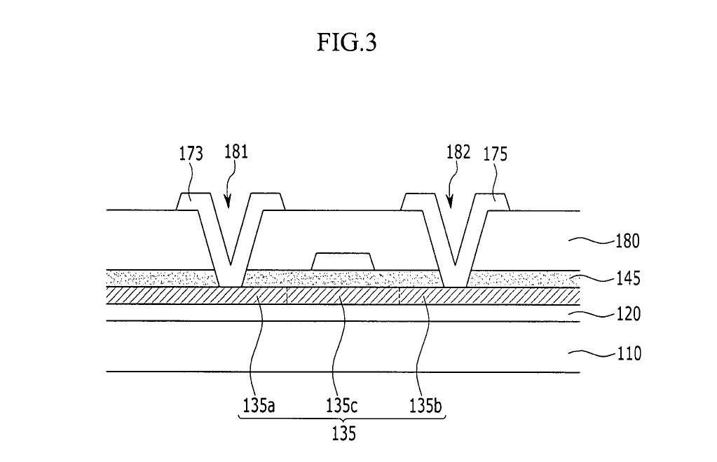

Hereafter, a thin film transistor including the polycrystalline silicon layer formed in the above-described method as an active layer will be described with reference to FIG. 3 along with FIGS. 1A to 2F.

FIG. 3 illustrates a cross-sectional view showing a thin film transistor in accordance with one embodiment of this disclosure.

A buffer layer 120 is formed on a substrate 110, and a polycrystalline silicon layer 135 is formed on the buffer layer 120. The polycrystalline silicon layer 135 may be crystallized using the metal catalyst as described above. The polycrystalline silicon layer 135 includes a channel region 135c, a source region 135a, and a drain region 135b, and the source region 135a and the drain region 135b may be doped with a p-type or n-type impurity.

A metal oxide layer 145 is formed on the polycrystalline silicon layer 135.

The metal oxide layer 145 may be a gate insulation layer. As described above, when the polycrystalline silicon layer 135 is formed, a gettering metal layer 140 for removing the metal catalyst 50 is formed on the overall surface of the amorphous silicon layer 130 or polycrystalline silicon layer 135, and a heat treatment is performed. During the heat treatment, the metal oxide layer 145 may be formed by supplying oxygen gas. The metal oxide layer 145 may be used as a gate insulation layer of the thin film transistor.

The metal oxide layer 145 may include titanium oxide, molybdenum oxide, tungsten oxide, or aluminum oxide.

A gate electrode 124 overlapping with the channel region 135c of the polycrystalline silicon layer 135 is formed on the metal oxide layer 145.

An insulation layer 180 is formed on the gate electrode 124, and the insulation layer 180 includes contact holes 181 and 182 that expose the source region 135a and the drain region 135b of the polycrystalline silicon layer 135, respectively.

A source electrode 173 and a drain electrode 175 are formed on the insulation layer 180 to be connected to the source region 135a and the drain region 135b of the polycrystalline silicon layer 135, respectively, through the contact holes 181 and 182.

Hereafter, an organic light emitting device manufactured in accordance with another embodiment of this disclosure will be described. The organic light emitting device may include the thin film transistor as a switching and/or driving device, and the thin film transistor may include a polycrystalline silicon layer formed in the above-described method.

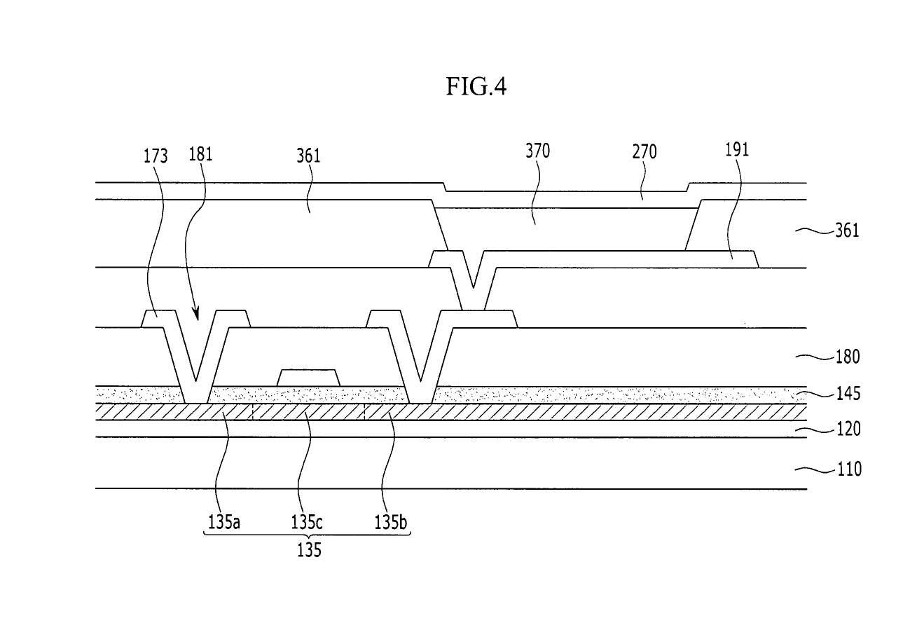

Hereafter, the organic light emitting device is described with reference to FIG. 4 along with FIGS. 1A to 2F.

FIG. 4 illustrates a cross-sectional view showing an organic light emitting device in accordance with one embodiment of this disclosure.

The organic light emitting device includes a plurality of signal lines and a plurality of pixels that are connected to the signal lines and arranged in a matrix form. FIG. 4 illustrates one pixel among the pixels, and each pixel includes a plurality of thin film transistors. Herein, one thin film transistor is illustrated for the sake of better understanding and ease of description.

A buffer layer 120 is formed on a substrate 110, and a polycrystalline silicon layer 135 is formed on the buffer layer 120. The polycrystalline silicon layer 135 may be crystallized using a metal catalyst as described above. The polycrystalline silicon layer 135 includes a channel region 135c, a source region 135a, and a drain region 135b, and the source region 135a and the drain region 135b may be doped with a p-type or n-type impurity.

A metal oxide layer 145 may be formed on the polycrystalline silicon layer 135. The metal oxide layer 145 may include a gate insulation layer. As described above, when the polycrystalline silicon layer 135 is formed, a gettering metal layer 140 for removing the metal catalyst 50 on the overall surface of the amorphous silicon layer 130 or the polycrystalline silicon layer 135, and a heat treatment is performed thereon. A metal oxide layer 145 may be formed by supplying oxygen gas during the heat treatment.

A gate electrode 124 overlapping with the channel region 135c of the polycrystalline silicon layer 135 is formed on the metal oxide layer 145.

An insulation layer 180 is formed on the gate electrode 124, and the insulation layer 180 includes contact holes 181 and 182 that expose the source region 135a and drain region 135b of the polycrystalline silicon layer 135, respectively.

A source electrode 173 and a drain electrode 175 that are respectively connected to the source region 135a and drain region 135b of the polycrystalline silicon layer 135 through the contact holes 181 and 182 are formed on the insulation layer 180.

An insulation layer 185 having the contact holes is formed on the source electrode 173 and the drain electrode 175.

A pixel electrode 191 connected to the drain electrode through the contact holes is formed on the insulation layer 185. The pixel electrode 191 may be an anode or a cathode.

A barrier rib 361 is formed on the insulation layer 185. The barrier rib 361 includes an opening that exposes the pixel electrode 191. An organic emission layer 370 is formed in the opening. The organic emission layer 370 may be formed of an organic material that emits light of any one color among three primary colors, such as red, green, and blue, or of a mixture of the organic material and an inorganic material. The organic light emitting device represents a desired image by a spatial sum of the primary color lights emitted from an emission layer.

The lower and upper portions of the organic emission layer 370 may further include an auxiliary layer for improving the luminous efficiency of the organic emission layer 370, and the auxiliary layer may be at least one among a hole injection layer (HIL), a hole transport layer (HTL), an electron injection layer (EIL), and an electron transport layer (ETL).

A common electrode 270 is formed on the organic emission layer 370 and the pixel electrode 191. The common electrode 270 is formed on the overall surface of the substrate, and the common electrode 270 may be a cathode or an anode.

The following examples illustrate this disclosure in more detail. However, the following are exemplary embodiments and are not limiting.

### EXAMPLE

A buffer layer was formed by depositing a silicon nitride on a glass substrate through a chemical vapor deposition (CVD) method. Subsequently, an amorphous silicon was deposited on the buffer layer through the CVD method, and nickel (Ni) was supplied thereto. Subsequently, a heat treatment was performed on the amorphous silicon supplied with the nickel (Ni) to form a polycrystalline silicon layer. Subsequently, molybdenum (Mo) was stacked as a gettering metal layer on the overall surface of the polycrystalline silicon layer in a thickness of about 500 Å, and a heat treatment was performed at about 550° C. for about 30 minutes. Subsequently, a gate electrode was formed on the gettering metal layer, a silicon nitride was deposited, and a portion of the polycrystalline silicon layer was exposed by performing a photolithography process. Subsequently, a source electrode and a drain electrode were formed by depositing aluminum and performing a photolithography process so as to fabricate a thin film transistor.

### Comparative Example

A thin film transistor was fabricated according to the same method as the example, except that the process of depositing molybdenum (Mo) on the overall surface of the polycrystalline silicon layer and performing the heat treatment was not performed.

Assessment—1

The concentration of nickel (Ni) existing in the buffer layer, the polycrystalline silicon layer, and the gettering metal layer of the thin film transistor according to the example was compared with the concentration of nickel (Ni) existing in the buffer layer and the polycrystalline silicon layer of the thin film transistor according to the comparative example.

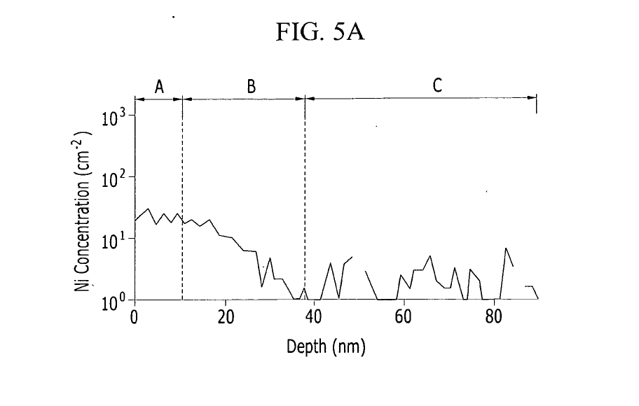

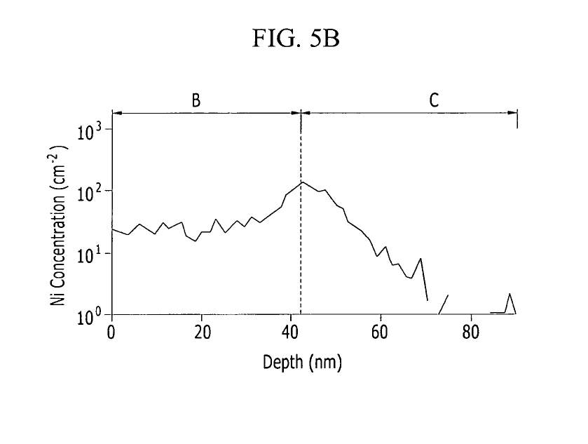

The results are shown in FIGS. 5A and 5B.

FIG. 5A illustrates a graph showing the concentration of nickel (Ni) distributed in a buffer layer, a polycrystalline silicon layer, and a gettering metal layer in a thin film transistor fabricated according to the example. FIG. 5B illustrates a graph showing the concentration of nickel (Ni) distributed in a buffer layer and a polycrystalline silicon layer in a thin film transistor fabricated according to the comparative example.

Referring to FIGS. 5A and 5B, while the thin film transistor according to the comparative example had a relatively high concentration level of nickel (Ni) remaining in the polycrystalline silicon layer (B) and the buffer layer (C), the thin film transistor according to the example had a remarkably decreased concentration level of nickel (Ni) remaining in the polycrystalline silicon layer (B) and the buffer layer (C), and a large amount of nickel (Ni) remains in the gettering metal layer (A).

It may be seen from the result that the concentration of nickel (Ni) remaining in the polycrystalline silicon layer may be considerably decreased by forming the gettering metal layer on the overall surface of the polycrystalline silicon layer and performing a heat treatment.

Assessment—2

Leakage current characteristics of the thin film transistors fabricated according to the example and comparative example were compared.

The results are shown in Table 1.

TABLE 1

| | Leakage current | Minimum leakage |
|---|---|---|
| [symbol] | (I_{off}) (at 5 V) | current (I_{off}) |
| Example | 0.88 | 0.08 |
| Comparative example | 1.16 | 0.82 |

[symbol]

indicates data missing or illegible when filed

Referring to Table 1, the thin film transistor fabricated according to the example had a remarkably small leakage current, compared with the thin film transistor fabricated according to the comparative example. It may be confirmed that the leakage current was decreased by reducing the amount of nickel (Ni) remaining in the polycrystalline silicon layer where a channel was formed.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope as set forth in the following claims.

What is claimed is:

1. A method for forming a polycrystalline silicon layer, comprising:
forming an amorphous silicon layer on a substrate;
forming a metal catalyst on the amorphous silicon layer;
forming a gettering metal layer on an overall surface of the amorphous silicon layer where the metal catalyst is formed; and
performing a heat treatment.

2. The method as claimed in claim 1, wherein the heat treatment is performed after the gettering metal layer is formed.

3. The method as claimed in claim 2, wherein the performing of the heat treatment includes supplying oxygen gas to the gettering metal layer.

4. The method as claimed in claim 2, wherein the heat treatment is performed at a temperature ranging from about 500 to about 850° C.

5. The method as claimed in claim 1, wherein the performing of the heat treatment includes:
performing a primary heat treatment after the forming of the amorphous silicon layer; and
performing a secondary heat treatment after the forming of the gettering metal layer.

6. The method as claimed in claim 5, wherein the performing of the secondary heat treatment includes supplying oxygen gas to the gettering metal layer.

7. The method as claimed in claim 5, wherein the primary heat treatment is performed at a temperature ranging from about 500 to about 850° C., and
the secondary heat treatment is performed at a temperature ranging from about 450 to about 750° C.

8. The method as claimed in claim 1, wherein the metal catalyst includes one of nickel (Ni), silver (Ag), gold (Au), copper (Cu), aluminum (Al), tin (Sn), cadmium (Cd), palladium (Pd), an alloy thereof, and a combination thereof, and
the gettering metal layer includes one of titanium (Ti), hafnium (Hf), scandium (Sc), zirconium (Zr), vanadium (V), tantalum (Ta), chromium (Cr), molybdenum (Mo), tungsten (W), manganese (Mn), rhenium (Re), ruthenium (Ru), osmium (Os), cobalt (Co), rhodium (Rh), iridium (Ir), platinum (Pt), yttrium (Y), lanthanum (La), cerium (Ce), praseodymium (Pr), neodymium (Nd), dysprosium (Dy), holmium (Ho), aluminum (Al), an alloy thereof, and a combination thereof.

9. The method as claimed in claim 1, wherein the gettering metal layer is formed in a thickness not thicker than about 1000 Å.

10. A thin film transistor, comprising:
a polycrystalline silicon layer formed according to the method as claimed in claim 1;
a gate insulation layer disposed on the polycrystalline silicon layer;
a gate electrode disposed on the gate insulation layer and overlapping with the polycrystalline silicon layer; and
a source electrode and a drain electrode electrically connected to the polycrystalline silicon layer.

11. The thin film transistor as claimed in claim 10, wherein the gate insulation layer includes a metal oxide.

12. The thin film transistor as claimed in claim 11, wherein the metal oxide is formed by oxidation of the gettering metal layer during the performing of the heat treatment.

13. The thin film transistor as claimed in claim 11, wherein the gate insulation layer has a thickness not thicker than about 1000 Å.

14. An organic light emitting device, comprising:
a polycrystalline silicon layer formed according to the method as claimed in claim 1;
a gate insulation layer disposed on the polycrystalline silicon layer;
a gate electrode disposed on the gate insulation layer and overlapping with the polycrystalline silicon layer;
a source electrode and a drain electrode electrically connected to the polycrystalline silicon layer;
a pixel electrode electrically connected to the drain electrode;
a common electrode confronting the pixel electrode; and
an organic emission layer disposed between the pixel electrode and the common electrode.

15. The organic light emitting device as claimed in claim 14, wherein the gate insulation layer includes a metal oxide.

16. The organic light emitting device as claimed in claim 15, wherein the metal oxide is formed by oxidation of the gettering metal layer during the performing of the heat treatment.

17. The organic light emitting device as claimed in claim 15, wherein the gate insulation layer has a thickness not thicker than about 1000 Å.
